(19) United States
(12) Patent Application Publication
(10) Pub. No.: US 2025/0386579 A1
(43) Pub. Date: Dec. 18, 2025

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Taichi FUKUDA, Yokohama Kanagawa (JP); Shotaro BABA, Kawasaki Kanagawa (JP); Hiroki NEMOTO, Meguro Tokyo (JP); Tomoaki INOKUCHI, Yokohama Kanagawa (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 19/023,622

(22) Filed: Jan. 16, 2025

(30) Foreign Application Priority Data
Jun. 13, 2024 (JP) 2024-096174

(51) Int. Cl. H10D 64/23; H10D 30/63; H10D 62/10; H10D 62/832; H10D 64/27; H10D 64/64

(52) U.S. Cl. CPC H10D 64/252; H10D 62/124; H10D 62/832; H10D 64/511; H10D 64/647; H10D 30/63

(57) ABSTRACT

According to one embodiment, a semiconductor device includes first to third electrodes, a semiconductor member, first and second insulating members. The semiconductor member includes a first semiconductor region. The first semiconductor region includes first to fourth partial regions. The first electrode portion is in contact with the fourth partial region. The first insulating member includes first and second insulating regions. The first insulating region is between the third electrode and the fourth partial region in the second direction. The second insulating region is between the first partial region and the third electrode in the first direction. The second insulating member includes a first insulating portion. The first insulating portion is between the second partial region and the first electrode portion in the first direction.

### CROSS-REFERENCE TO RELATED APPLICATIONS

This application is based upon and claims the benefit of priority from Japanese Patent Application No. 2024-096174, filed on Jun. 13, 2024; the entire contents of which are incorporated herein by reference.

### FIELD

Embodiments described herein relate generally to a semiconductor device.

### BACKGROUND

It is desirable to improve the characteristics of semiconductor devices.

### BRIEF DESCRIPTION OF THE DRAWINGS

FIG. 1 is a schematic cross-sectional view illustrating a semiconductor device according to a first embodiment;

FIG. 2 is a schematic cross-sectional view illustrating a semiconductor device according to the first embodiment;

FIG. 3 is a schematic cross-sectional view illustrating a semiconductor device according to the first embodiment;

FIG. 4 is a schematic cross-sectional view illustrating a semiconductor device according to the first embodiment;

FIG. 5 is a schematic cross-sectional view illustrating a semiconductor device according to the first embodiment;

FIG. 6 is a schematic cross-sectional view illustrating a semiconductor device according to the first embodiment;

FIG. 7 is a schematic cross-sectional view illustrating a semiconductor device according to the first embodiment; and

FIG. 8 is a schematic perspective view illustrating a semiconductor device according to a second embodiment.

### DETAILED DESCRIPTION

According to one embodiment, a semiconductor device includes a first electrode, a second electrode, a third electrode, a semiconductor member, a first insulating member, and a second insulating member. A direction from the first electrode to the second electrode is along a first direction. The second electrode includes a first electrode portion and a second electrode portion connected to the first electrode portion. The semiconductor member includes a first semiconductor region. The first semiconductor region includes a first partial region, a second partial region, a third partial region, and a fourth partial region. A second direction from the first partial region to the second partial region crosses the first direction. The third partial region is between the first partial region and the second partial region in the second direction. The first partial region is between the first electrode and the third electrode in the first direction. The second partial region is between the first electrode and the first electrode portion in the first direction. The fourth partial region is between the third partial region and the second electrode portion in the first direction. The fourth partial region is between the third electrode and the first electrode portion in the second direction. The first electrode portion is in contact with the fourth partial region. The first insulating member includes a first insulating region and a second insulating region. The first insulating region is between the third electrode and the fourth partial region in the second direction. The second insulating region is between the first partial region and the third electrode in the first direction. The second insulating member includes a first insulating portion. The first insulating portion is between the second partial region and the first electrode portion in the first direction.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

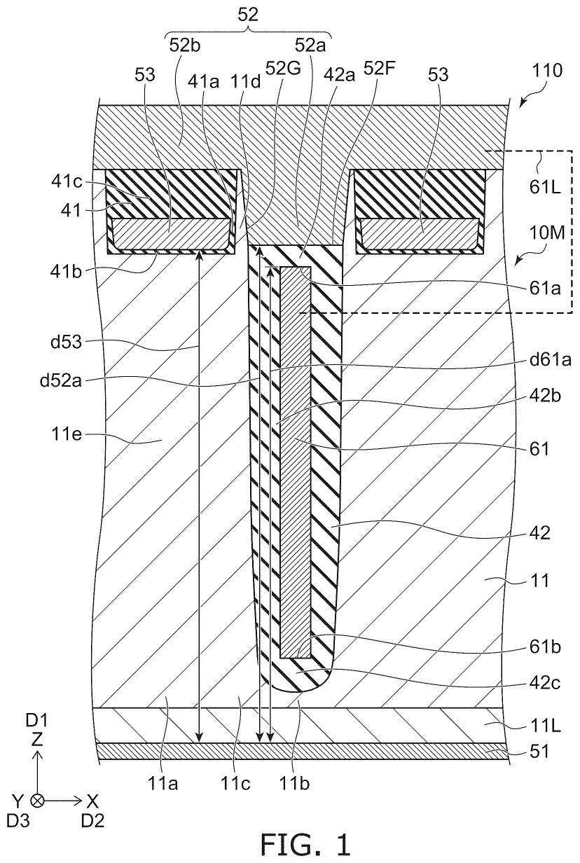

FIG. 1 is a schematic cross-sectional view illustrating a semiconductor device according to a first embodiment.

As shown in FIG. 1, a semiconductor device 110 according to the embodiment includes a first electrode 51, a second electrode 52, a third electrode 53, a semiconductor member 10M, a first insulating member 41, and a second insulating member 42. The semiconductor member 10M includes a first semiconductor region 11.

A direction from the first electrode 51 to the second electrode 52 is along a first direction D1. The first direction D1 is defined as a Z-axis direction. One direction perpendicular to the Z-axis direction is defined as an X-axis direction. A direction perpendicular to the Z-axis and X-axis directions is defined as a Y-axis direction.

The second electrode 52 includes a first electrode portion 52a and a second electrode portion 52b. The second electrode portion 52b is connected to the first electrode portion 52a. The first electrode portion 52a extends in the first direction D1 and a second direction D2. In the first direction D1, the first electrode portion 52a is located between the first electrode 51 and the second electrode portion 52b.

The first semiconductor region 11 is provided, for example, between the first electrode 51 and the second electrode 52 in the first direction D1. The first semiconductor region 11 is substantially in layered along the X-Y plane.

The first semiconductor region 11 includes a first partial region 11a, a second partial region 11b, a third partial region 11c, and a fourth partial region 11d. A second direction D2 from the first partial region 11a to the second partial region 11b crosses the first direction D1. The second direction D2 may be, for example, the X-axis direction.

The third partial region 11c is between the first partial region 11a and the second partial region 11b in the second direction D2. The first partial region 11a is between the first electrode 51 and the third electrode 53 in the first direction D1. The second partial region 11b is between the first electrode 51 and the first electrode portion 52a in the first direction D1. For example, a portion that overlaps the third electrode 53 in the first direction D1 corresponds to the first partial region 11a. For example, a portion that overlaps the first electrode portion 52a in the first direction D1 corresponds to the second partial region 11b.

The fourth partial region 11d is between the third partial region 11c and the second electrode portion 52b in the first direction D1. The fourth partial region 11d is between the third electrode 53 and the first electrode portion 52a in the second direction D2. The fourth partial region 11d is located between the first insulating member 41 and the first electrode portion 52a in the second direction D2. The first electrode portion 52a is in contact with the fourth partial region 11d. For example, the fourth partial region 11d does not overlap the first electrode portion 52a in the first direction D1.

The boundaries between the first partial region 11a, the second partial region 11b, the third partial region 11c, and the fourth partial region 11d may be clear or unclear.

In the first semiconductor region 11, the first partial region 11a, the second partial region 11b, the third partial region 11c, and the fourth partial region 11d may be of n-type (first conductivity type). These partial regions may be of p-type (second conductivity type). In the following description, these partial regions are referred to as be of n-type (first conductivity type).

The first insulating member 41 includes a first insulating region 41a and a second insulating region 41b. The first insulating region 41a is between the third electrode 53 and the fourth partial region 11d in the second direction D2. The first insulating region 41a contacts, for example, the third electrode 53 and the fourth partial region 11d. The fourth partial region 11d is between the first insulating region 41a and the first electrode portion 52a in the second direction D2. The second insulating region 41b is between the first partial region 11a and the third electrode 53 in the first direction D1. The second insulating region 41b may contact, for example, the first partial region 11a and the third electrode 53. The first insulating member 41 electrically insulates, for example, the third electrode 53 from the semiconductor member 10M (first semiconductor region 11).

The second insulating member 42 includes a first insulating portion 42a. The first insulating portion 42a is between the second partial region 11b and the first electrode portion 52a in the first direction D1.

For example, current flowing between the first electrode 51 and the second electrode 52 can be controlled by a potential of the third electrode 53. The potential of the third electrode 53 may be, for example, a potential based on a potential of the second electrode 52. The first electrode 51 functions as, for example, a drain electrode. The second electrode 52 functions as, for example, a source electrode. The third electrode 53 functions as, for example, a gate electrode. The semiconductor device 110 is, for example, a transistor.

For example, the potential of the third electrode 53 controls the current flowing through the fourth partial region 11d. The fourth partial region 11d is at least a part of the carrier region. For example, the first electrode portion 52a and the fourth partial region 11d form a Schottky contact.

In the semiconductor device 110, the region through which the current flows may not include a p-type region or an n-type region. High-speed recovery is obtained. For example, a short gate length can be obtained, which can suppress losses.

In the embodiment, the first insulating portion 42a is provided between the second partial region 11b and the first electrode portion 52a in the first direction D1. As a result, the bottom face of the first electrode portion 52a (first face 52F, see FIG. 1) does not come into contact with the first semiconductor region 11. On the other hand, the side face of the first electrode portion 52a (second face 52G, see FIG. 1) comes into Schottky contact with the fourth partial region 11d. It has been found that this configuration can suppress, for example, leakage current.

For example, in a reference example, the bottom face of the first electrode portion 52a, which forms a Schottky contact, contacts the first semiconductor region 11. It was found that in such a reference example, the leakage current is likely to be large. It was found that the leakage current is large in the region including the bottom face of the first electrode portion 52a. Such leakage current occurs particularly noticeably when the work function of the first electrode portion 52a, which is related to the barrier height, is low.

In the embodiment, by providing the first insulating portion 42a, the bottom face of the first electrode portion 52a does not come into contact with the first semiconductor region 11. Thereby, it becomes possible to effectively suppress the leakage current, for example, even when the work function is small. According to the embodiment, it is possible to provide a semiconductor device with improved characteristics.

In addition to the work function of the material, the barrier height also depends on the morphology of the surface of the first semiconductor region 11, the crystal characteristics of the first electrode portion 52a, and the film quality of the first electrode portion 52a. These characteristics may change due to variations in manufacturing conditions. These characteristics may also change over time. In the embodiment, by providing the first insulating portion 42a, leakage current caused by fluctuations in these characteristics can be stably and effectively suppressed.

For example, for the same work function, the leakage current in the embodiment can be reduced to about 1/50 or less of the leakage current in the reference example.

As shown in FIG. 1, the first electrode portion 52a includes a first face 52F and a second face 52G. The first face 52F crosses the second face 52G. The first face 52F faces the first electrode 51. The first face 52F corresponds to the bottom face. The first face 52F is not in contact with the first semiconductor region 11. The second face 52G is in contact with the fourth partial region 11d. The second face 52G is, for example, a side face.

In the embodiment, a width of the first face 52F of the first electrode portion 52a along the second direction D2 may be smaller than the maximum width of the first electrode portion 52a along the second direction D2. For example, a width of the upper end of the first electrode portion 52a along the second direction D2 may be greater than or equal to the width of the first face 52F along the second direction D2. The upper end of the first electrode portion 52a is the end on the side of the second electrode portion 52b in the first direction D1.

As shown in FIG. 1, the first insulating member 41 may further include a third insulating region 41c. The third insulating region 41c is between the third electrode 53 and at least a part of the second electrode portion 52b in the first direction D1. The third insulating region 41c contacts, for example, the third electrode 53, a part of the second electrode portion 52b, and the fourth partial region 11d. The fourth partial region 11d is between the first insulating region 41a and the first electrode portion 52a in the second direction D2. A length of the third insulating region 41c in the first direction D1 may be longer than a length of the third electrode 53 in the first direction D1, for example.

As shown in FIG. 1, the semiconductor device 110 may further include a first semiconductor layer 11L. The first semiconductor layer 11L is provided between the first electrode 51 and the first semiconductor region 11. For example, an impurity concentration in the first semiconductor layer 11L is higher than an impurity concentration in the first semiconductor region 11. The first semiconductor layer 11L may be in contact with the first electrode 51. By providing the first semiconductor layer 11L, for example, a low on-resistance can be obtained. The first partial region 11a, the second partial region 11b, and the third partial region 11c may be in contact with the first electrode 51, in the case where the semiconductor device 110 does not include the first semiconductor layer 11L.

As shown in FIG. 1, the semiconductor device 110 may further include a first conductive member 61. The first conductive member 61 is between the second partial region 11b and the first electrode portion 52a in the first direction D1. At least a part of the first insulating portion 42a is between the first conductive member 61 and the first electrode portion 52a.

The first semiconductor region 11 may further include a fifth partial region 11e. The fifth partial region 11e is between the first partial region 11a and the second insulating region 41b in the first direction D1. The fifth partial region 11e may be in contact with the second insulating region 41b. The second insulating member 42 may further include a second insulating portion 42b. The second insulating portion 42b is between the fifth partial region 11e and the first conductive member 61 in the second direction D2.

The second insulating member 42 may further include, for example, a third insulating portion 42c. The third insulating portion 42c is between the second partial region 11b and the first conductive member 61 in the first direction D1. The second insulating member 42 may be provided around the first conductive member 61. The second insulating member 42 electrically insulates, for example, the first conductive member 61 from the semiconductor member 10M (first semiconductor region 11).

The first conductive member 61 may function as, for example, a field plate. For example, the concentration of an electric field can be suppressed. Stable operation can be easily obtained. For example, the first conductive member 61 may be electrically connected to the second electrode 52. The electrical connection may be obtained by, for example, a connecting member 61L. The first conductive member 61 may be electrically floating.

As shown in FIG. 1, the first conductive member 61 includes a first end 61a and a second end 61b. The first end 61a is between the second end 61b and the first insulating portion 42a in the first direction D1. The first end 61a is, for example, the upper end. The second end 61b is the lower end. A distance along the first direction D1 between the first electrode 51 and the first end 61a is defined as an upper end distance d61a. A distance along the first direction D1 between the first electrode 51 and the third electrode 53 is defined as a third electrode distance d53. For example, the upper end distance d61a may be shorter than the third electrode distance d53. For example, stable operation is easier to obtain.

As shown in FIG. 1, a distance between the first electrode 51 and the first electrode portion 52a in the first direction D1 is defined as a first electrode portion distance d52a. In this example, the first electrode portion distance d52a is longer than the third electrode distance d53 (the distance between the first electrode 51 and the third electrode 53 in the first direction D1). As described below, the relationship between these distances can be modified in various ways.

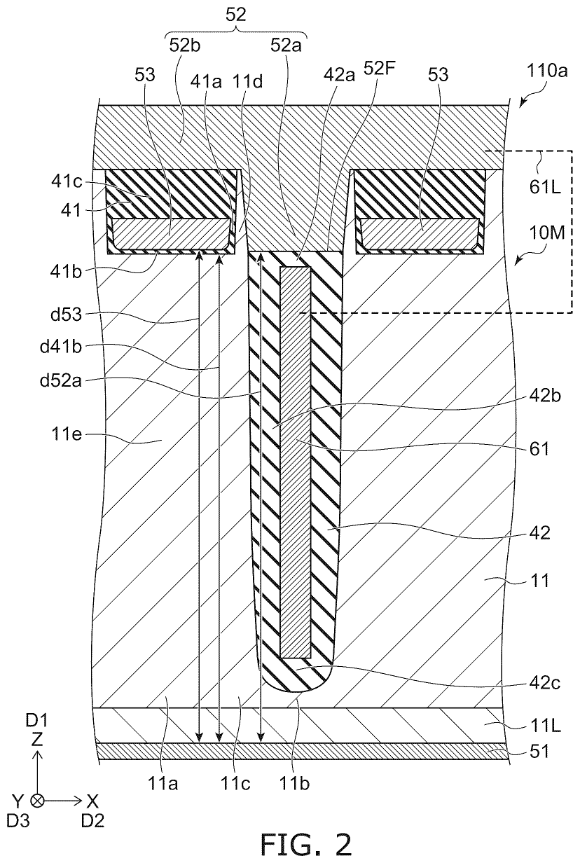

FIG. 2 is a schematic cross-sectional view illustrating a semiconductor device according to the first embodiment.

As shown in FIG. 2, in a semiconductor device 110a according to the embodiment, the first electrode portion distance d52a is shorter than the third electrode distance d53. Except for this, the configuration of the semiconductor device 110a may be the same as the configuration of the semiconductor device 110.

As shown in FIG. 2, a distance along the first direction D1 between the first electrode 51 and the second insulating region 41b is defined as a second insulating region distance d41b. In this example, the first electrode portion distance d52a is longer than the second insulating region distance d41b.

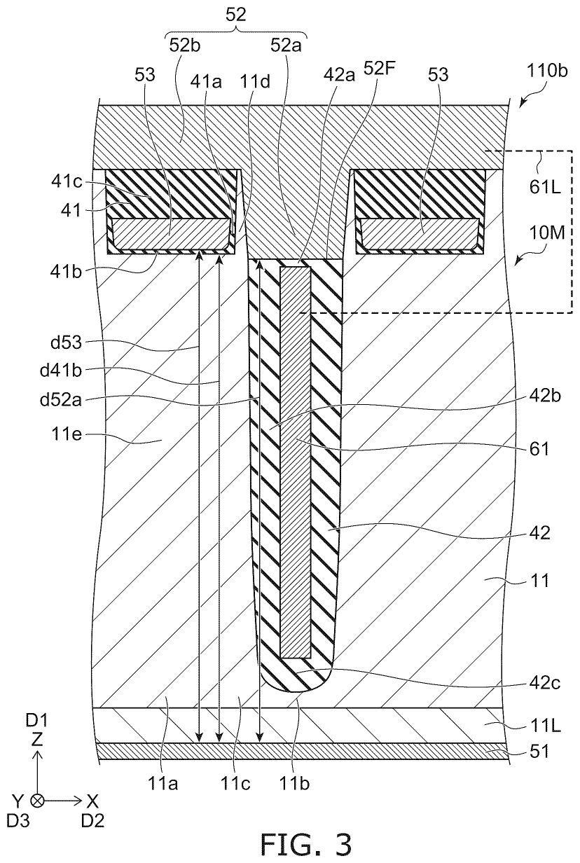

FIG. 3 is a schematic cross-sectional view illustrating a semiconductor device according to the first embodiment.

As shown in FIG. 3, in a semiconductor device 110b according to the embodiment, the first electrode portion distance d52a is shorter than the second insulating region distance d41b. Except for this, the configuration of the semiconductor device 110b may be the same as the configuration of the semiconductor device 110.

The leakage current can also be suppressed in the semiconductor device 110a and the semiconductor device 110b. The relationship between the first electrode portion distance d52a and other distances described for the semiconductor device 110a, the semiconductor device 110a, and the semiconductor device 110b may be applied to various semiconductor devices described below.

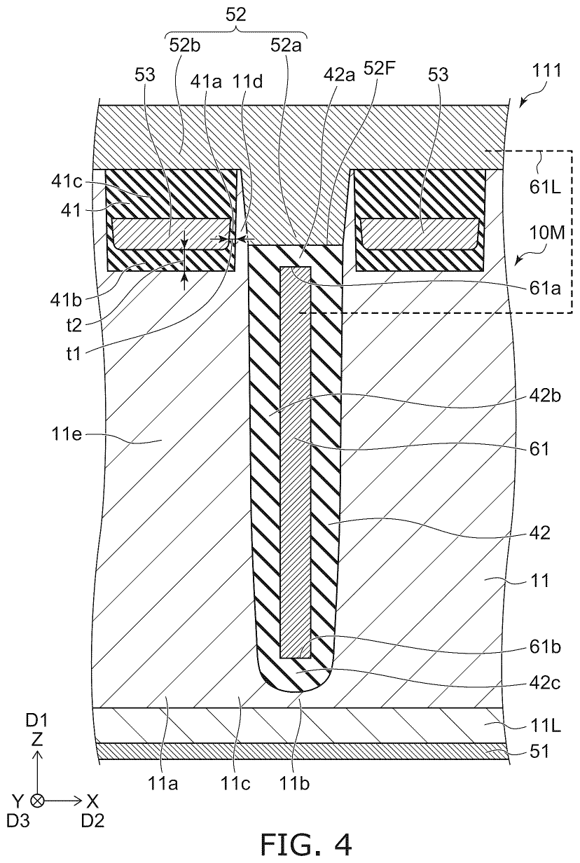

FIG. 4 is a schematic cross-sectional view illustrating a semiconductor device according to the first embodiment.

As shown in FIG. 4, in a semiconductor device 111 according to the embodiment, the shape of the first insulating member 41 differs from that in the semiconductor device 110. Except for this, the configuration of the semiconductor device 111 may be the same as the configuration of the semiconductor device 110.

As shown in FIG. 4, the first insulating region 41a has a first thickness t1 along the second direction D2. The second insulating region 41b has a second thickness t2 along the first direction D1. The second thickness t2 is thicker than the first thickness t1. This thickness relationship can reduce losses due to the capacitance between the bottom of the gate and the drain, for example. For example, the loss Qgd in the semiconductor device 111 can be reduced to about 0.61 times the loss Qgd in the semiconductor device 110.

In the embodiment, a ratio (t2/t1) of the second thickness t2 to the first thickness t1 may be, for example, 1.1 or more. Losses can be effectively suppressed. The ratio (t2/t1) may be, for example, 10 or less.

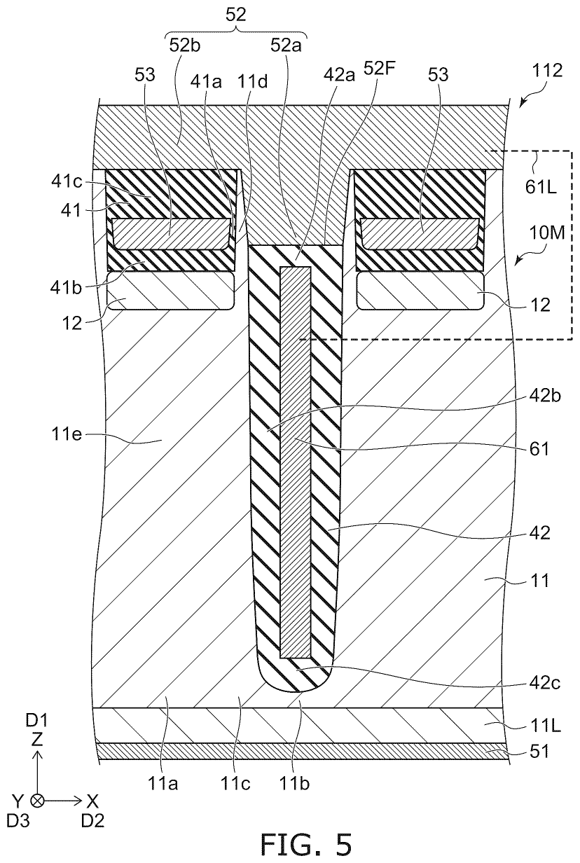

FIG. 5 is a schematic cross-sectional view illustrating a semiconductor device according to the first embodiment.

As shown in FIG. 5, in a semiconductor device 112 according to the embodiment, a second semiconductor region 12 is provided. Except for this, the configuration of semiconductor device 112 may be the same as the configuration of semiconductor device 111 or semiconductor device 110.

In the semiconductor device 112, the semiconductor member 10M further includes a second semiconductor region 12. The second semiconductor region 12 is between the first partial region 11a and the second insulating region 41b in the first direction D1. In this example, the second semiconductor region 12 is between the fifth partial region 11e and the second insulating region 41b in the first direction D1.

In one example, the first semiconductor region 11 is of one of the first and second conductivity types (e.g., n-type), and the second semiconductor region 12 is of the other one of the first and second conductivity types (e.g., p-type). By providing such a second semiconductor region 12, for example, it is possible to reduce losses due to the capacitance between the bottom of the gate and the drain.

In the embodiment, the first semiconductor region 11 and the second semiconductor region 12 may satisfy a first condition or a second condition. In the first condition, the first semiconductor region 11 is of one of the first conductivity type and the second conductivity type. In the first condition, the second semiconductor region 12 is of the other one of the first conductivity type and the second conductivity type.

In the second condition, the first semiconductor region 11 and the second semiconductor region 12 are of the first conductivity type (or may be of the second conductivity type). In the second condition, a second impurity concentration in the second semiconductor region 12 is different from a first impurity concentration in the first semiconductor region 11. For example, the second impurity concentration is lower than the first impurity concentration.

For example, the semiconductor member 10M (first semiconductor region 11 and second semiconductor region 12) may include silicon. In this case, the second semiconductor region 12 may include at least one first element (p-type impurity) selected from the group consisting of boron and aluminum. The first semiconductor region 11 does not include the first element. Alternatively, the second concentration of the first element in the second semiconductor region 12 is higher than the first concentration of the first element in the first semiconductor region 11.

For example, the first semiconductor region 11 may include at least one (n-type impurity) selected from the group consisting of phosphorus and arsenic. The second semiconductor region 12 may also include at least one (n-type impurity) selected from the group consisting of phosphorus and arsenic. For example, the second semiconductor region 12 may include p-type impurities with a concentration higher than the concentration of the n-type impurity. For example, the second semiconductor region 12 may be formed by co-doping.

In the semiconductor device 112, the second semiconductor region 12 may be provided while applying the relationship between the first thickness t1 and the second thickness t2 described for the semiconductor device 111. The loss Qgd in such a semiconductor device 112 can be reduced to approximately 0.58 times the loss Qgd in the semiconductor device 110.

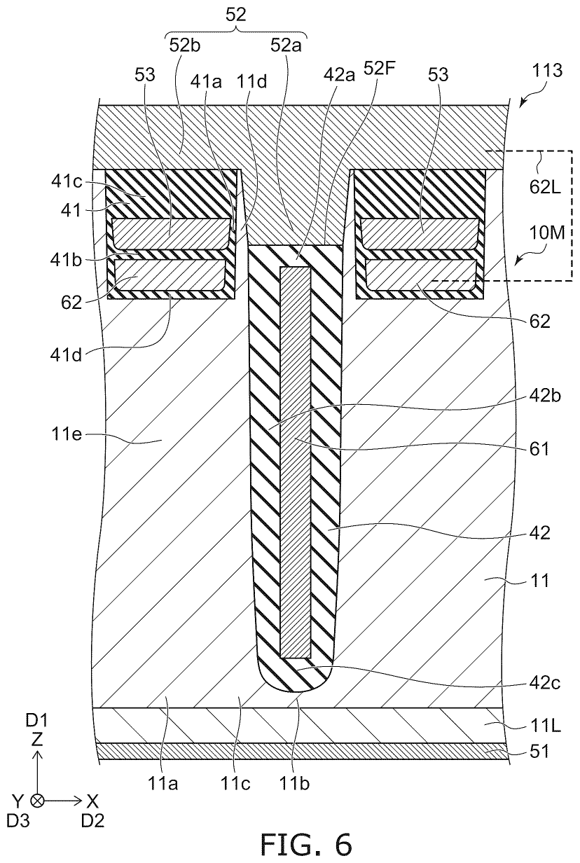

FIG. 6 is a schematic cross-sectional view illustrating a semiconductor device according to the first embodiment.

As shown in FIG. 6, in a semiconductor device 113 according to the embodiment, a second conductive member 62 is provided. Except for this, the configuration of the semiconductor device 113 may be the same as the configuration of the semiconductor device 110.

The semiconductor device 113 further includes a second conductive member 62. The second conductive member 62 is between the first partial region 11a and the third electrode 53 in the first direction D1. In this example, the second conductive member 62 is between the fifth partial region 11e and the third electrode 53 in the first direction D1.

The first insulating member 41 further includes a fourth insulating region 41d. The second insulating region 41b is between the second conductive member 62 and the third electrode 53 in the first direction D1. The fourth insulating region 41d is between the first partial region 11a and the second conductive member 62 in the first direction D1. In this example, the fourth insulating region 41d is between the fifth partial region 11e and the second conductive member 62 in the first direction D1.

By providing the second conductive member 62, for example, the loss due to the capacitance between the bottom of the gate and the drain can be reduced. The loss Qgd in such a semiconductor device 113 can be reduced to about 0.05 times the loss Qgd in the semiconductor device 110.

The second conductive member 62 may be electrically connected to the second electrode 52. The electrical connection may be obtained by the connecting member 61L or the like.

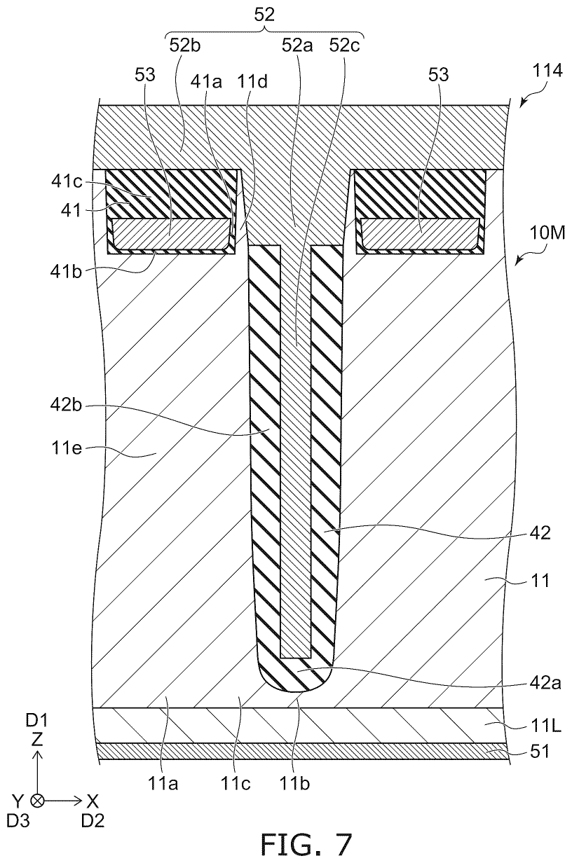

FIG. 7 is a schematic cross-sectional view illustrating a semiconductor device according to the first embodiment.

As shown in FIG. 7, in a semiconductor device 114 according to the embodiment, the shape of the second electrode 52 is different from that in the semiconductor device 110. Except for this, the configuration of the semiconductor device 114 may be the same as the configuration of the semiconductor device 110.

In the semiconductor device 114, the second electrode 52 includes a third electrode portion 52c. The third electrode portion 52c is connected to the first electrode portion 52a. The third electrode portion 52c is provided between the first insulating portion 42a and the first electrode portion 52a. In the semiconductor device 114 as well, leakage current is suppressed.

In the semiconductor device 114, the first semiconductor region 11 may further include the fifth partial region 11e. The fifth partial region 11e is between the first partial region 11a and the second insulating region 41b in the first direction D1. The second insulating member 42 further includes the second insulating portion 42b. The second insulating portion 42b is between the fifth partial region 11e and the third electrode portion 52c in the second direction D2. The third electrode portion 52c, for example, suppresses electric field concentration.

### Second Embodiment

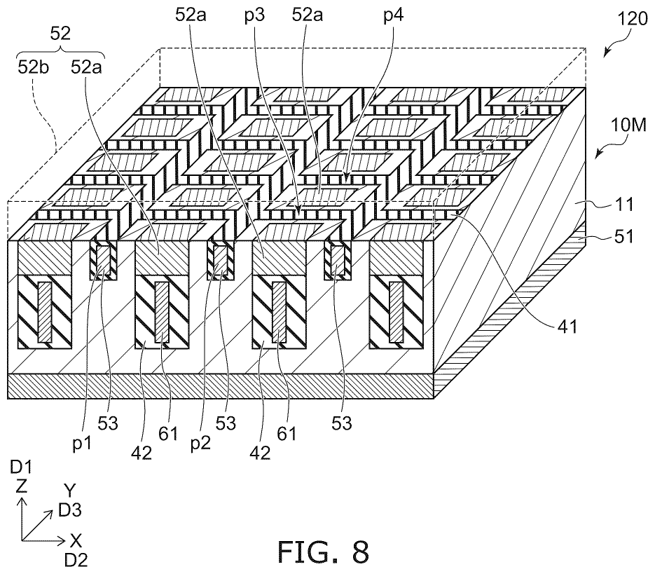

FIG. 8 is a schematic perspective view illustrating a semiconductor device according to a second embodiment.

As shown in FIG. 8, in a semiconductor device 120 according to the embodiment, the second electrode 52 includes a plurality of first electrode portions 52a. In the semiconductor device 120, the various configurations described in relation to the first embodiment may be applied.

In the semiconductor device 120, the third electrode 53 includes a first portion p1 and a second portion p2. One of the plurality of first electrode portions 52a is between the first portion p1 and the second portion p2 in the second direction D2. The third electrode 53 may include a third portion p3 and a fourth portion p4. For example, another one of the plurality of first electrode portions 52a is between the third portion p3 and the fourth portion p4 in the third direction D3. The third direction D3 crosses a plane including the first direction D1 and the second direction D2. The third direction D3 may be, for example, the Y-axis direction.

According to the semiconductor device 120, it is easy to provide multiple first electrode portions 52a at a high density. For example, at least a part of the third electrode 53 may be in a lattice configuration extending along the second direction D2 and the third direction D3. The planar shape of at least a part of the third electrode 53 may be in a honeycomb shape. Electrical connection of the third electrode 53 is easy.

In the embodiment, the semiconductor member 10M may include silicon or diamond. The semiconductor member 10M may include a compound semiconductor. The compound semiconductor may include, for example, SiC, SiGe, GaN, or GaAs.

The first electrode 51 may include, for example, a metal. The first electrode 51 may include, for example, at least one selected from the group consisting of Al, Au, Ag, Cu, Ni, Ti, and W. The second electrode 52 may include, for example, at least one selected from the group consisting of Ni, Ti, Pt, Ir, TiO₂, and Co. The third electrode 53 may include a metal or polysilicon. At least one of the first conductive member 61 and the second conductive member 62 may include a metal or polysilicon.

In the embodiment, information regarding the shape of the semiconductor region can be obtained, for example, by electron microscope observation. Information regarding the composition and element concentration in the semiconductor region can be obtained, for example, by EDX (Energy Dispersive X-ray Spectroscopy) or SIMS (Secondary Ion Mass Spectrometry). Information regarding the composition in the semiconductor region can be obtained, for example, by reciprocal space mapping.

The embodiment may include the following Technical proposals:

### (Technical Proposal 1)

A semiconductor device, comprising:
a first electrode;
a second electrode, a direction from the first electrode to the second electrode being along a first direction, the second electrode including a first electrode portion and a second electrode portion connected to the first electrode portion;
a third electrode,
a semiconductor member including a first semiconductor region, the first semiconductor region including a first partial region, a second partial region, a third partial region, and a fourth partial region, a second direction from the first partial region to the second partial region crossing the first direction, the third partial region being between the first partial region and the second partial region in the second direction, the first partial region being between the first electrode and the third electrode in the first direction, the second partial region being between the first electrode and the first electrode portion in the first direction, the fourth partial region being between the third partial region and the second electrode portion in the first direction, the fourth partial region being between the third electrode and the first electrode portion in the second direction, the first electrode portion being in contact with the fourth partial region;
a first insulating member including a first insulating region and a second insulating region, the first insulating region being between the third electrode and the fourth partial region in the second direction, the second insulating region being between the first partial region and the third electrode in the first direction; and
a second insulating member including a first insulating portion, the first insulating portion being between the second partial region and the first electrode portion in the first direction.

### (Technical Proposal 2)

The Semiconductor Device According to Technical Proposal 1, Further Including:
a first conductive member,
the first conductive member being between the second partial region and the first electrode portion in the first direction, and
at least a part of the first insulating portion being between the first conductive member and the first electrode portion.

### (Technical Proposal 3)

The semiconductor device according to Technical proposal 2, wherein
the first semiconductor region further includes a fifth partial region,
the fifth partial region is between the first partial region and the second insulating region in the first direction,
the second insulating member further includes a second insulating portion, and
the second insulating portion is between the fifth partial region and the first conductive member in the second direction.

### (Technical Proposal 4)

The semiconductor device according to Technical proposal 2 or 3, wherein
the first conductive member includes a first end and a second end,
the first end is between the second end and the first insulating portion in the first direction, and
an upper end distance along the first direction between the first electrode and the first end is shorter than a third electrode distance along the first direction between the first electrode and the third electrode.

### (Technical Proposal 5)

The semiconductor device according to any one of Technical proposals 2-4, wherein
the first conductive member is electrically connected to the second electrode.

### (Technical Proposal 6)

The semiconductor device according to Technical proposal 1, wherein
the second electrode further includes a third electrode portion connected to the first electrode portion, and
the third electrode portion is provided between the first insulating portion and the first electrode portion.

### (Technical Proposal 7)

The semiconductor device according to Technical proposal 6, wherein
the first semiconductor region further includes a fifth partial region,
the fifth partial region is between the first partial region and the second insulating region in the first direction,
the second insulating member further includes a second insulating portion, and
the second insulating portion is between the fifth partial region and the third electrode portion in the second direction.

### (Technical Proposal 8)

The semiconductor device according to any one of Technical proposal 1-3, wherein
a first electrode portion distance along the first direction between the first electrode and the first electrode portion is longer than a third electrode distance along the first direction between the first electrode and the third electrode.

### (Technical Proposal 9)

The semiconductor device according to any one of Technical proposal 1-8, wherein
the first electrode portion and the fourth electrode portion form a Schottky contact.

### (Technical Proposal 10)

The semiconductor device according to any one of Technical proposal 1-9, wherein
the first insulating region has a first thickness along the second direction,
the second insulating region has a second thickness along the first direction, and
the second thickness being thicker than the first thickness.

### (Technical Proposal 11)

The semiconductor device according to Technical proposal 10, wherein
a ratio of the second thickness to the first thickness is greater than or equal to 1.1.

### (Technical Proposal 12)

The semiconductor device according to any one of Technical proposals 1-11, wherein
the semiconductor member further includes a second semiconductor region,
the second semiconductor region is between the first partial region and the second insulating region in the first direction,
the semiconductor member includes silicon,
the second semiconductor region includes at least one first element selected from the group consisting of boron and aluminum, and
the first semiconductor region does not include the first element, or a second concentration of the first element in the second semiconductor region is higher than a first concentration of the first element in the first semiconductor region.

### (Technical Proposal 13)

The semiconductor device according to Technical proposal 12, wherein
the first semiconductor region includes at least one selected from the group consisting of phosphorus and arsenic.

### (Technical Proposal 14)

The semiconductor device according to any one of Technical proposals 1-11, wherein
the semiconductor member further includes a second semiconductor region,
the second semiconductor region is between the first partial region and the second insulating region in the first direction,
t first semiconductor region and the second semiconductor region satisfy a first condition or a second condition,
in the first condition, the first semiconductor region is of one of the first conductivity type and the second conductivity type, and the second semiconductor region is of other one of the first conductivity type and the second conductivity type, and
in the second condition, the first semiconductor region and the second semiconductor region are of the first conductivity type, and a second impurity concentration in the second semiconductor region is different from a first impurity concentration in the first semiconductor region.

### (Technical Proposal 15)

The semiconductor device according to any one of Technical proposals 1-11, wherein
the second conductive member is between the first partial region and the third electrode in the first direction,
the first insulating member further includes a fourth insulating region,
the second insulating region is between the second conductive member and the third electrode in the first direction, and
the fourth insulating region is between the first partial region and the second conductive member in the first direction.

### (Technical Proposal 16)

The semiconductor device according to any one of Technical proposals 1-15, wherein
the first insulating member further includes a third insulating region, and
the third insulating region is between the third electrode and at least a part of the second electrode portion in the first direction.

### (Technical Proposal 17)

The semiconductor device according to any one of Technical proposals 1-16, wherein
the first electrode portion includes a first face and a second face,
the first face crosses the second face,
the first face faces the first electrode,
the first face does not contact the first semiconductor region, and
the second face contacts the fourth partial region.

### (Technical Proposal 18)

The semiconductor device according to any one of Technical proposals 1-17, wherein
the second electrode includes a plurality of the first electrode portions,
the third electrode includes a first portion and a second portion, and
one of the plurality of the first electrode portions is between the first portion and the second portion in the second direction.

### (Technical Proposal 19)

The semiconductor device according to Technical proposal 18, wherein
the third electrode includes a third portion and a fourth portion,
another of the plurality of first electrode portions is between the third portion and the fourth portion in a third direction, and
the third direction crosses a plane including the first direction and the second direction.

### (Technical Proposal 20)

The semiconductor device according to Technical proposal 19, wherein
at least a part of the third electrode is in a lattice configuration extending along the second direction and the third direction.

According to the embodiment, a semiconductor device with improved characteristics can be provided.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the semiconductor devices such as electrodes, semiconductor members, semiconductor regions, insulating members, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor devices practicable by an appropriate design modification by one skilled in the art based on the semiconductor devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
a first electrode;
a second electrode, a direction from the first electrode to the second electrode being along a first direction, the second electrode including a first electrode portion and a second electrode portion connected to the first electrode portion;
a third electrode,
a semiconductor member including a first semiconductor region, the first semiconductor region including a first partial region, a second partial region, a third partial region, and a fourth partial region, a second direction from the first partial region to the second partial region crossing the first direction, the third partial region being between the first partial region and the second partial region in the second direction, the first partial region being between the first electrode and the third electrode in the first direction, the second partial region being between the first electrode and the first electrode portion in the first direction, the fourth partial region being between the third partial region and the second electrode portion in the first direction, the fourth partial region being between the third electrode and the first electrode portion in the second direction, the first electrode portion being in contact with the fourth partial region;
a first insulating member including a first insulating region and a second insulating region, the first insulating region being between the third electrode and the fourth partial region in the second direction, the second insulating region being between the first partial region and the third electrode in the first direction; and
a second insulating member including a first insulating portion, the first insulating portion being between the second partial region and the first electrode portion in the first direction.

2. The semiconductor device according to claim 1, further including:
a first conductive member,
the first conductive member being between the second partial region and the first electrode portion in the first direction, and
at least a part of the first insulating portion being between the first conductive member and the first electrode portion.

3. The semiconductor device according to claim 2, wherein
the first semiconductor region further includes a fifth partial region,
the fifth partial region is between the first partial region and the second insulating region in the first direction,
the second insulating member further includes a second insulating portion, and
the second insulating portion is between the fifth partial region and the first conductive member in the second direction.

4. The semiconductor device according to claim 2, wherein
the first conductive member includes a first end and a second end,
the first end is between the second end and the first insulating portion in the first direction, and
an upper end distance along the first direction between the first electrode and the first end is shorter than a third electrode distance along the first direction between the first electrode and the third electrode.

5. The semiconductor device according to claim 2, wherein
the first conductive member is electrically connected to the second electrode.

6. The semiconductor device according to claim 1, wherein
the second electrode further includes a third electrode portion connected to the first electrode portion, and
the third electrode portion is provided between the first insulating portion and the first electrode portion.

7. The semiconductor device according to claim 6, wherein
the first semiconductor region further includes a fifth partial region,
the fifth partial region is between the first partial region and the second insulating region in the first direction,
the second insulating member further includes a second insulating portion, and
the second insulating portion is between the fifth partial region and the third electrode portion in the second direction.

8. The semiconductor device according to claim 1, wherein
a first electrode portion distance along the first direction between the first electrode and the first electrode portion is longer than a third electrode distance along the first direction between the first electrode and the third electrode.

9. The semiconductor device according to claim 1, wherein
the first electrode portion and the fourth electrode portion form a Schottky contact.

10. The semiconductor device according to claim 1, wherein
the first insulating region has a first thickness along the second direction,
the second insulating region has a second thickness along the first direction, and
the second thickness being thicker than the first thickness.

11. The semiconductor device according to claim 10, wherein
a ratio of the second thickness to the first thickness is greater than or equal to 1.1.

12. The semiconductor device according to claim 1, wherein
the semiconductor member further includes a second semiconductor region,
the second semiconductor region is between the first partial region and the second insulating region in the first direction,
the semiconductor member includes silicon,
the second semiconductor region includes at least one first element selected from the group consisting of boron and aluminum, and
the first semiconductor region does not include the first element, or a second concentration of the first element in the second semiconductor region is higher than a first concentration of the first element in the first semiconductor region.

13. The semiconductor device according to claim 12, wherein
the first semiconductor region includes at least one selected from the group consisting of phosphorus and arsenic.

14. The semiconductor device according to claim 1, wherein
the semiconductor member further includes a second semiconductor region,
the second semiconductor region is between the first partial region and the second insulating region in the first direction,
the first semiconductor region and the second semiconductor region satisfy a first condition or a second condition,
in the first condition, the first semiconductor region is of one of the first conductivity type and the second conductivity type, and the second semiconductor region is of other one of the first conductivity type and the second conductivity type, and
in the second condition, the first semiconductor region and the second semiconductor region are of the first conductivity type, and a second impurity concentration in the second semiconductor region is different from a first impurity concentration in the first semiconductor region.

15. The semiconductor device according to claim 1, wherein
the second conductive member is between the first partial region and the third electrode in the first direction,
the first insulating member further includes a fourth insulating region,
the second insulating region is between the second conductive member and the third electrode in the first direction, and
the fourth insulating region is between the first partial region and the second conductive member in the first direction.

16. The semiconductor device according to claim 1, wherein
the first insulating member further includes a third insulating region, and
the third insulating region is between the third electrode and at least a part of the second electrode portion in the first direction.

17. The semiconductor device according to claim 1, wherein
the first electrode portion includes a first face and a second face,
the first face crosses the second face,
the first face faces the first electrode,
the first face does not contact the first semiconductor region, and
the second face contacts the fourth partial region.

18. The semiconductor device according to claim 1, wherein
the second electrode includes a plurality of the first electrode portions,
the third electrode includes a first portion and a second portion, and
one of the plurality of the first electrode portions is between the first portion and the second portion in the second direction.

19. The semiconductor device according to claim 18, wherein
the third electrode includes a third portion and a fourth portion,
another of the plurality of first electrode portions is between the third portion and the fourth portion in a third direction, and
the third direction crosses a plane including the first direction and the second direction.

20. The semiconductor device according to claim 19, wherein
at least a part of the third electrode is in a lattice configuration extending along the second direction and the third direction.
